(19) United States
(12) Patent Application Publication
(10) Pub. No.: US 2025/0324838 A1
(43) Pub. Date: Oct. 16, 2025

(54) ELECTRONIC DEVICE

(71) Applicant: Samsung Display Co., LTD., Yongin-si (KR)

(72) Inventors: NAMJIN KIM, Yongin-si (KR); YEONJU SEO, Yongin-si (KR); WONJANG KI, Yongin-si (KR)

(21) Appl. No.: 19/042,907

(22) Filed: Jan. 31, 2025

(30) Foreign Application Priority Data
Apr. 11, 2024 (KR) 10-2024-0048592

(51) Int. Cl. H10H 29/853; G06F 3/044; H10H 29/30; H10H 29/854

(52) U.S. Cl. CPC H10H 29/853; G06F 3/0445; H10H 29/30; H10H 29/854

(57) ABSTRACT

An electronic device includes a display panel including a base layer including an active area, which includes a hole area, an encapsulation layer covering light-emitting elements and including a first encapsulation inorganic layer, an encapsulation organic layer, and a second encapsulation inorganic layer, and dam patterns disposed on the hole area, and an input sensor including an organic pattern layer which overlaps a first sensing insulating layer, first conductive patterns, a second sensing insulating layer, second conductive patterns, a third sensing insulating layer, and the hole area, is disposed on the first sensing insulating layer, and is covered on the second sensing insulating layer. A module hole overlapping the hole area is defined, and the second encapsulation inorganic layer, the first sensing insulating layer, the second sensing insulating layer, and the third sensing insulating layer contact each other on at least one top surface of the dam patterns.

This application claims priority to Korean Patent Application No. 10-2024-0048592, filed on Apr. 11, 2024, and all the benefits accruing therefrom under U.S.C. § 119, the content of which in its entirety is herein incorporated by reference.

### BACKGROUND

### 1. Field

The disclosure herein relates to an electronic device having improved quality.

### 2. Description of the Related Art

Electronic devices are activated according to an electrical signal. Such an electronic device may include devices constituted by various electronic components such as a display panel that displays an image and an input sensor that senses an external input. The electronic components may be electrically connected to each other by signal lines, which are variously arranged.

### SUMMARY

The disclosure provides an electronic device having improved quality.

An embodiment of the inventive concept provides an electronic device including: a display panel including a base layer including an active area, which includes a hole area and a pixel area surrounding the hole area, light-emitting elements disposed on the pixel area, an encapsulation layer covering the light-emitting elements and including a first encapsulation inorganic layer, an encapsulation organic layer, and a second encapsulation inorganic layer, and dam patterns disposed on the hole area; an input sensor including which are disposed on the encapsulation layer and comprising a first sensing insulating layer, first conductive patterns, a second sensing insulating layer, second conductive patterns, a third sensing insulating layer, and an organic pattern layer which overlaps the hole area and is disposed on the first sensing insulating layer and is covered on the second sensing insulating layer; a cover organic layer disposed on the input sensor, and a window disposed on the cover organic layer, where a module hole which passes through the display panel, the input sensor, and the cover organic layer, which overlap the hole area, is defined, each of the dam patterns surrounds the module hole, and the second encapsulation inorganic layer, the first sensing insulating layer, the second sensing insulating layer, and the third sensing insulating layer contact each other on at least one top surface of the dam patterns.

In an embodiment, the dam patterns may include a first dam pattern to a fifth dam pattern spaced apart from each other in a direction toward the module hole on the pixel area, and each of the first dam pattern to the fifth dam pattern may include a first insulating pattern, a first pattern disposed on the first insulating pattern, a second pattern that contacts the first pattern, and a second insulating pattern covering the second pattern, wherein the second pattern protrudes between a side surface of the first insulating pattern and a side surface of the second insulating pattern and defines a tip part.

In an embodiment, a boundary of the organic pattern layer may be defined by the fourth dam pattern within the hole area, and the second encapsulation inorganic layer, the first sensing insulating layer, the second sensing insulating layer, and the third sensing insulating layer may contact each other on the fourth dam pattern.

In an embodiment, the display panel may include: a first insulating layer disposed on the base layer; a first semiconductor pattern disposed on the first insulating layer; a second insulating layer covering the first semiconductor pattern and disposed on the first insulating layer; a first gate overlapping the first semiconductor pattern and disposed on the second insulating layer; a third insulating layer covering the first gate and disposed on the second insulating layer; a second semiconductor pattern disposed on the third insulating layer; a fourth insulating layer covering the second semiconductor pattern and disposed on the third insulating layer; a second gate overlapping the second semiconductor pattern and disposed on the fourth insulating layer; a fifth insulating layer covering the second gate and disposed on the fourth insulating layer; a first connection electrode disposed on the fifth insulating layer and connected to the first semiconductor pattern through a first contact hole which passes through the second insulating layer to the fifth insulating layer; a sixth insulating layer covering the first connection electrode and disposed on the fifth insulating layer; a second connection electrode disposed on the sixth insulating layer and connected to the first connection electrode through a second contact hole which passes through the sixth insulating layer; and a seventh insulating layer covering the second connection electrode and disposed on the sixth insulating layer, wherein a light-emitting element of the light-emitting elements may be connected to the second connection electrode through a third contact hole which passes through the seventh insulating layer.

In an embodiment, the base layer may include a first organic layer, a first inorganic layer disposed on the first organic layer, a second organic layer disposed on the first inorganic layer, and a second inorganic layer disposed on the second organic layer, which are sequentially laminated, and each of the first organic layer and the second organic layer may include polyimide, and each of the first inorganic layer and the second inorganic layer comprises an inorganic material.

In an embodiment, the electronic device may further include a light-blocking pattern overlapping the first semiconductor pattern and disposed within the second inorganic layer.

In an embodiment, each of the first insulating layer to the fifth insulating layer may include an inorganic material, and each of the sixth and seventh insulating layers may include an organic material.

In an embodiment, the first insulating pattern may include a same material as that of the sixth insulating layer, and the second insulating pattern comprises a same material as that of the seventh insulating layer, and the first pattern may include a same material as that of the first connection electrode, and the second pattern comprises a same material as that of the second connection electrode.

In an embodiment, each of the first dam pattern to the fourth dam pattern may further include a first dummy pattern overlapping the first pattern and disposed on the second insulating layer and a second dummy pattern overlapping the first dummy pattern and disposed on the third insulating layer.

In an embodiment, the fifth dam pattern may further include a dummy pattern disposed within the second inorganic layer, and the first pattern of the fifth dam pattern may be connected to the dummy pattern through a contact hole which passes through the second inorganic layer, the first insulating layer to the fifth insulating layer, and the first insulating pattern.

In an embodiment, the organic pattern layer may be disposed on an area between the first dam pattern and the second dam pattern, an area between the second dam pattern and the third dam pattern, and an area between the third dam pattern and the fourth dam pattern.

In an embodiment, the second encapsulation inorganic layer, the first sensing insulating layer, the second sensing insulating layer, and the third sensing insulating layer may contact each other on a top surface of the second dam pattern, a top surface of the third dam pattern, and a top surface of the fourth dam pattern.

In an embodiment, the fourth dam pattern may further include a first additional pattern disposed on the second insulating pattern and a second additional pattern disposed on the first additional pattern, and the fifth dam pattern may further include a third additional pattern disposed on the second insulating pattern, wherein each of the first additional pattern to third additional pattern may include an organic material.

In an embodiment, a portion of the organic pattern layer may be disposed between the fourth dam pattern and the fifth dam pattern, the second encapsulation inorganic layer, the first sensing insulating layer, the second sensing insulating layer, and the third sensing insulating layer may contact each other on a top surface of the fourth dam pattern and a top surface of the fifth dam pattern.

In an embodiment, the first encapsulation inorganic layer may be covering the first dam pattern to the fifth dam pattern.

In an embodiment, at least two tip parts of the tip parts respectively included in the first dam pattern to the fifth dam pattern may face each other.

In an embodiment, the first encapsulation inorganic layer and the second encapsulation inorganic layer may contact each other on the at least one top surface of the dam pattern on which the second encapsulation inorganic layer, the first sensing insulating layer, the second sensing insulating layer, and the third sensing insulating layer contact each other.

In an embodiment, each of the first sensing insulating layer, the second sensing insulating layer, and the third sensing insulating layer may include an inorganic material.

In an embodiment, the electronic device may further include a fourth sensing insulating layer disposed between the cover organic layer and the third sensing insulating layer and comprising an organic material.

In an embodiment, the electronic device may further include a camera module overlapping the module hole.

An embodiment of the inventive concept provides an electronic device including: a display panel displays an image based on input image data provided from the processor and including a base layer including an active area, which includes a hole area and a pixel area surrounding the hole area, light-emitting elements disposed on the pixel area, an encapsulation layer covering the light-emitting elements and including a first encapsulation inorganic layer, an encapsulation organic layer, and a second encapsulation inorganic layer, and dam patterns disposed on the hole area; a driving unit drives the display panel based on the input image data and a brightness value of the display panel; an input sensor including which are disposed on the encapsulation layer and comprising a first sensing insulating layer, first conductive patterns, a second sensing insulating layer, second conductive patterns, a third sensing insulating layer, and an organic pattern layer which overlaps the hole area and is disposed on the first sensing insulating layer and is covered on the second sensing insulating layer; a cover organic layer disposed on the input sensor, and a window disposed on the cover organic layer, where a module hole which passes through the display panel, the input sensor, and the cover organic layer, which overlap the hole area, is defined, each of the dam patterns surrounds the module hole, and the second encapsulation inorganic layer, the first sensing insulating layer, the second sensing insulating layer, and the third sensing insulating layer contact each other on at least one top surface of the dam patterns.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of an electronic device according to the inventive concept;

FIG. 2 is an exploded perspective view of an embodiment of the electronic device according to the inventive concept;

FIG. 3 is a block diagram of an embodiment of an electronic device according to the inventive concept;

FIG. 4 is a plan view of an embodiment of a display panel next (adjacent) to a hole according to the inventive concept;

FIG. 5 is a cross-sectional view of the electronic device, taken along line I-I′ of FIG. 2;

FIG. 6 is a cross-sectional view of the electronic device, taken along line II-II′ of FIG. 2;

FIG. 7 is an enlarged cross-sectional view of an area AA′ of FIG. 6;

FIG. 8 is a cross-sectional view of an embodiment of an electronic device according to the inventive concept;

FIG. 9 is a cross-sectional view of an embodiment of an electronic device according to the inventive concept;

FIG. 10 is a cross-sectional view of an embodiment of an electronic device according to the inventive concept; and

FIG. 11 is an enlarged cross-sectional view of an area BB′ of FIG. 10.

### DETAILED DESCRIPTION

In this specification, it will also be understood that when one component (or region, layer, portion) is referred to as being ‘on’, ‘connected to’, or ‘coupled to’ another component, it may be directly disposed/connected/coupled on/to the one component, or an intervening third component may also be present.

Like reference numerals refer to like elements throughout. Also, in the drawing figures, the thickness, ratio, and dimensions of components are exaggerated for clarity of illustration. The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above’, “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Unless otherwise defined, all terms (including technical and scientific terms) used herein have the same meaning as commonly understood by a person of ordinary skill in the art to which this invention belongs. In addition, terms such as those defined in commonly used dictionaries should be interpreted as having meanings consistent with their meanings in the context of the relevant technology, and unless explicitly defined, it should not be interpreted in an overly idealistic or overly formal sense.

Hereinafter, embodiments of the inventive concept will be described with reference to the accompanying drawings.

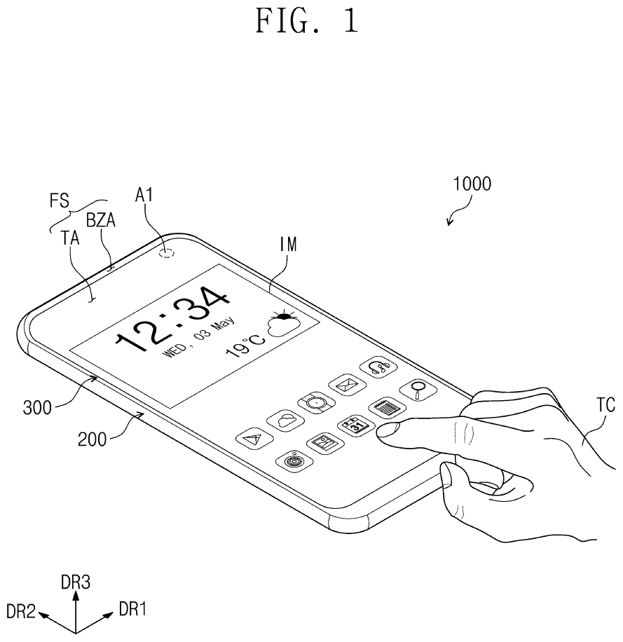

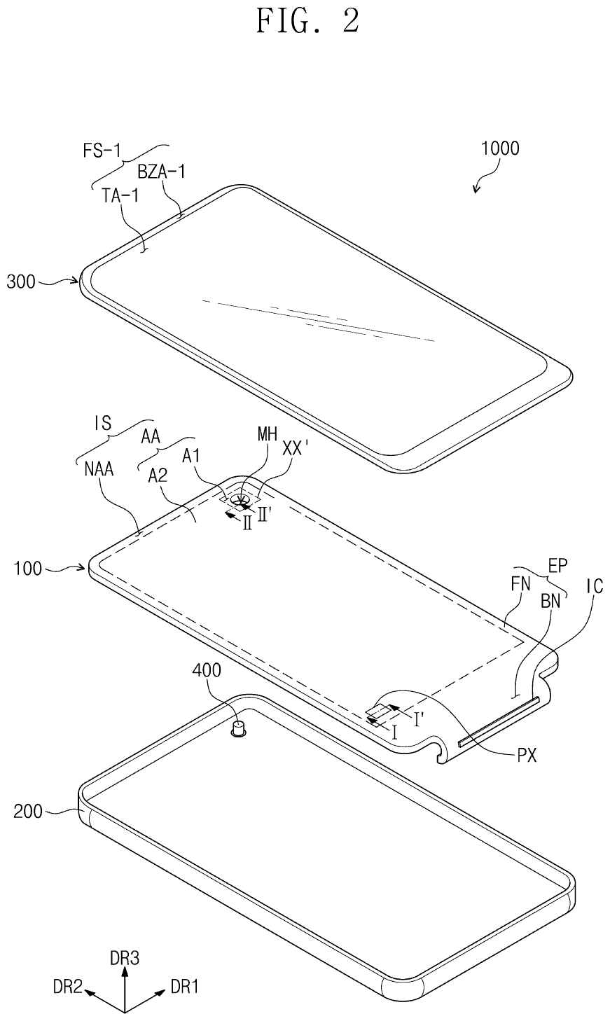

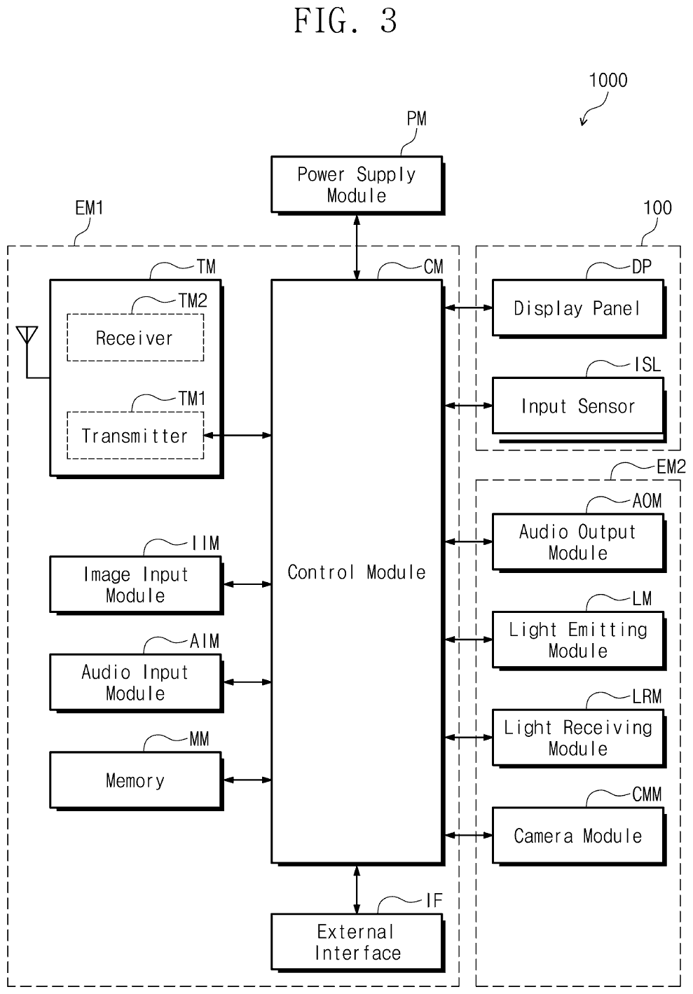

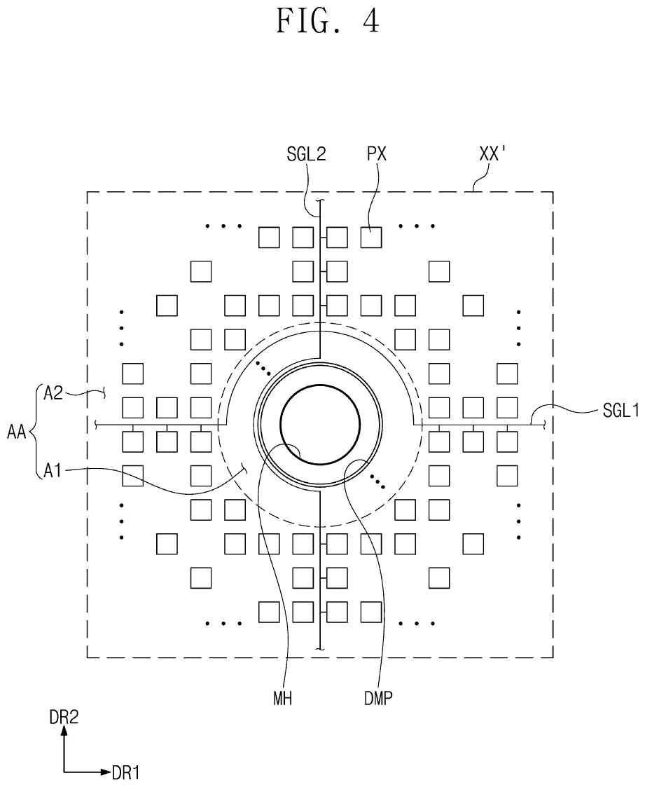

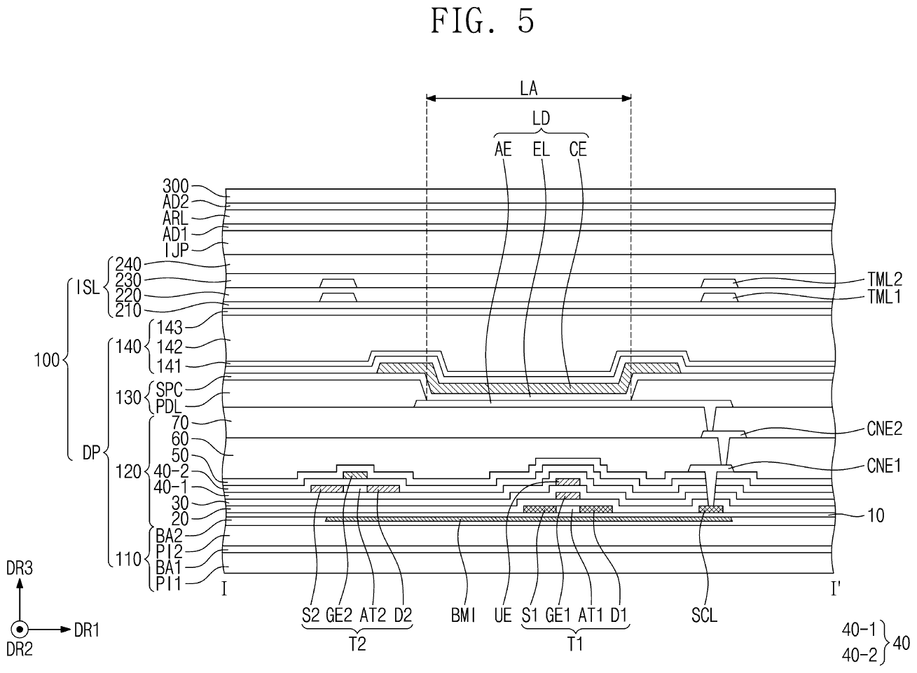

FIG. 1 is a perspective view of an embodiment of an electronic device according to the inventive concept. FIG. 2 is an exploded perspective view of an embodiment of the electronic device according to the inventive concept. FIG. 3 is a block diagram of an embodiment of an electronic device according to the inventive concept. FIG. 4 is a plan view of an embodiment of a display panel next (adjacent) to a hole according to the inventive concept. FIG. 5 is a cross-sectional view of the electronic device, taken along line I-I′ of FIG. 2.

Referring to FIGS. 1 and 2, an electronic device 1000 may include a display surface FS parallel to each of a first direction DR1 and a second direction DR2. The electronic device 1000 may display an image IM on the display surface FS in a third direction DR3. The display surface FS on which the image IM is displayed may correspond to a front surface of the electronic device 1000. The display surface FS may include a light transmission area TA and a bezel area BZA surrounding at least a portion of the light transmission area TA.

The electronic device 1000 may be a display device to provide an image (a dynamic image or a static image) IM to a user through the display surface FS. The electronic device 1000 may be an input device to sense an external input TC. In FIG. 1, a clock and icons are illustrated in an embodiment of the image IM. The display surface FS of the electronic device 1000 may correspond to a front surface FS-1 of a window 300 (refer to FIG. 2). Thus, the light transmission area TA of the electronic device 1000 may be defined to correspond to a light transmission area TA-1 of the window 300, and the bezel area BZA of the electronic device 1000 may be defined to correspond to a bezel area BZA-1 of the window 300.

In this embodiment, a front surface (or a top surface) or a rear surface (or a bottom surface) of each of members may be defined based on a direction in which the image IM is displayed. The front and rear surfaces may be opposite to each other in the third direction DR3. A normal direction of each of the front and rear surfaces may be parallel to the third direction DR3. A spaced distance between the front and rear surfaces in the third direction DR3 may correspond to a thickness of the electronic device 1000 in the third direction DR3.

The electronic device 1000 in an embodiment of the inventive concept may sense the external input (e.g., a user's input) TC applied from the outside. The external input TC includes various types of external inputs such as a portion of user's body, light, heat, a pressure, or the like. In this embodiment, the user's input TC is shown as a user's hand applied to the front surface FS of the window 300.

However, this is merely one of embodiments. In an embodiment, as described above, the external input TC may be provided in various shapes, for example. The electronic device 1000 may sense the external input TC applied to a side surface or the rear surface of the electronic device 1000 according to a structure of the electronic device 1000, but is not limited to an illustrative embodiment.

The electronic device 1000 in an embodiment may include a hole area A1 that overlaps the light transmission area TA. The hole area A1 may be defined as an area where an electronic module 400 of the display module 100, which will be described later, is disposed. A module hole MH (refer to FIG. 2) of the display module 100 may be defined on the hole area A1.

The electronic device 1000 may receive an external signal desired for the electronic module 400 through the hole area A1 or may provide a signal output from the electronic module 400 to the outside. In an embodiment of the inventive concept, the hole area A1 may be provided inside the light transmission area TA, and thus, a surface area of the bezel area BZA for forming the hole area A1 may be reduced.

Referring to FIG. 2, the electronic device 1000 may include a display module 100, a housing 200, a window 300, and an electronic module 400. The window 300 and the housing 200 may be coupled to define an outer appearance of the electronic device 1000. The electronic device 1000 in an embodiment may further include a cover organic layer IJP (refer to FIG. 5) and an anti-reflection layer ARL (refer to FIG. 5) disposed on the display module 100. The related explanation will be provided later.

The window 300 may include an insulating panel. In an embodiment, the window 300 may include or consist of glass, plastic, or any combinations thereof, for example. As described above, the front surface FS-1 of the window 300 may define the display surface FS of the electronic device 1000. The window 300 may include a light transmission area TA-1 and a bezel area BZA-1 next (adjacent) to the light transmission area TA-1. The light transmission area TA-1 may be an optically transparent area. In an embodiment, the light transmission area TA-1 may be an area having a visible light transmittance of about 90% or more, for example. The bezel area BZA-1 may be an area having light transmittance that is relatively less than that of the light transmission area TA-1. The bezel area BZA-1 may define a shape of the light transmission area TA-1.

The bezel area BZA-1 may have a predetermined color. The bezel area BZA-1 may be defined by a bezel layer provided separately from a transparent substrate defining the light transmission area TA-1 or defined by an ink layer provided to be inserted into and applied to the transparent substrate.

The display module 100 may include an electronic panel EP and a driving circuit IC. The electronic panel EP may display an image IM and detect a user's input TC. The front surface IS of the electronic panel EP includes an active area AA and a peripheral area NAA.

In this embodiment, the active area AA may be an area on which the image IM is displayed, and also, the external input TC is sensed. The active area AA may be an area on which a plurality of pixels PX is disposed.

The active area AA may overlap at least a portion of the light transmission area TA. In an embodiment, the light transmission area TA may overlap an entirety of the surface or at least a portion of the active area AA, for example. Thus, the user may visually recognize the image IM through the light transmission area TA or provide the external input TC. However, this is merely one of embodiments. In an embodiment, an area of the active area AA, on which the image IM is displayed, and an area of the active area AA, on which the external input TC is sensed, may be separated from each other, for example, but is not limited to an illustrative embodiment.

The peripheral area NAA may be an area covered by the bezel area BZA. The peripheral area NAA is next (adjacent) to the active area AA. The peripheral area NAA may surround the active area AA. The peripheral area NAA may be an area on which the image IM is not displayed. A driving circuit or a driving line for driving the active area AA may be disposed on the peripheral area NAA.

In an embodiment, a portion of the peripheral area NAA of the electronic panel EP may be bent. In an embodiment, the electronic panel EP may include a flat portion FN and a bent portion BN, for example. The flat portion FN may be assembled in a state substantially parallel to a plane defined by the first direction DR1 and the second direction DR2. The active area AA may be provided in the flat portion FN.

The bent portion BN may extend from the flat portion FN and be bent along a virtual bending axis. The bent portion BN may be assembled by being bent to face a rear surface of the flat portion FN. When the bent portion BN is assembled, the flat portions FN may overlap each other a plane, and thus, the bezel area BZA of the electronic device 1000 may be reduced. This is an illustrated in an embodiment, and in the electronic panel EP, the bent portion BN may be omitted.

The driving circuit IC may be disposed (e.g., mounted) on the bent portion BN. The driving circuit IC may be illustrated in the form of a chip in this embodiment, but is not limited thereto. In an embodiment, the driving circuit IC may be provided on a separate circuit board and electrically connected to the electronic panel EP through a flexible film or the like, for example.

The driving circuit IC may be electrically connected to the active area AA to transmit an electrical signal to the active area AA. In an embodiment, the driving circuit IC may include a data driving circuit and provide data signals to the pixels PX disposed on the active area AA, for example. In an alternative embodiment, the driving circuit IC may include a touch driving circuit and be electrically connected to an input sensor disposed on the active area AA, for example. This is merely one of embodiments, and the driving circuit IC may include various circuits in addition to the above-described circuits or may be designed to provide various electrical signals to the active area AA, but is not limited to any embodiment.

The electronic device 1000 in an embodiment may further include a main circuit board electrically connected to the electronic panel EP and the driving circuit IC. The main circuit board may include various driving circuits for driving the electronic panel EP and a connector for supplying power. The main circuit board may be a rigid printed circuit board (“PCB”), but is not limited thereto and may also be a flexible circuit board, but is not limited to any embodiment.

The electronic module 400 may be disposed below the display module 100. The electronic module 400 may overlap the module hole MH defined in the electronic panel EP and may receive an external input transmitted through the module hole MH or output a signal through the module hole MH.

FIG. 2 illustrates a single module hole MH having a circular shape in an embodiment, but it is not limited thereto, and the number of module holes MH may be defined to correspond to the number of electronic modules 400 disposed below the electronic panel EP, and the module hole may have either a polygonal or oval shape, but is not limited to any embodiment.

In an embodiment of the inventive concept, the hole area A1 having relatively high transmittance may be provided inside the active area AA, and thus, the electronic module 400 may be disposed to overlap the active area AA. Thus, a surface area of the bezel area BZA may be prevented from increasing.

The housing 200 may be coupled to the window 300 to provide a predetermined internal space and define an outer appearance of the electronic device 1000. Constituents of the electronic device 1000, such as the display module 100 and the electronic module 400, may be accommodated in the internal space.

The housing 200 may include a material having relatively high rigidity. In an embodiment, the housing 200 may include glass, plastic, or a metal or may include a plurality of frames and/or plates including or consisting of a combination of glass, plastic, and a metal, for example. The housing 200 may stably protect the constituents of the electronic device 1000, which are accommodated in the internal space, against an external impact.

Referring to FIG. 3, the electronic device 1000 may include a display module 100, a power supply module PM, a first electronic module EM1, and a second electronic module EM2. The display module 100, the power supply module PM, the first electronic module EM1, and the second electronic module EM2 may be electrically connected to each other.

FIG. 3 illustrates a display panel DP and an input sensor ISL of the constituents of the display module 100 as an example. The display panel DP may be a constituent that generates an image IM. The image IM generated by the display panel DP may be displayed on the display surface FS through the light transmission area TA so as to be visible to the external user. The input sensor ISL may sense an external input TC applied from the outside. As described above, the input sensor ISL may sense the external input TC provided to the window 300.

The power supply module PM may supply power desired for an overall operation of the electronic device 1000. The power supply module PM may include a general battery module.

The first electronic module EM1 and the second electronic module EM2 may include various functional modules for driving the electronic device 1000. The first electronic module EM1 may be directly disposed (e.g., mounted) on a mother board electrically connected to the electronic panel EP or may be disposed (e.g., mounted) on a separate board and electrically connected to the mother board through a connector (not shown).

The first electronic module EM1 may include a control module CM, a wireless communication module TM, an image input module IIM, an audio input module AIM, a memory MM, and an external interface IF. A portion of the modules may not be disposed (e.g., mounted) on the mother board but electrically connected to the mother board through a flexible circuit board.

The control module CM may control the overall operation of the electronic device 1000. The control module CM may be a micro processor. In an embodiment, the control module CM may activate or inactivate the display module 100, for example. The control module CM may control other modules such as the image input module IIM or the audio input module AIM on the basis of a touch signal received from the electronic panel EP.

The wireless communication module TM may transmit/receive a wireless signal to/from the other terminal by Bluetooth® or Wi-Fi line. The wireless communication module TM may transmit/receive an audio signal by a general communication line. The wireless communication module TM includes a transmitter TM1 modulating and transmitting a signal to be transmitted and a receiver TM2 demodulating the received signal.

The image input module IIM processes the image signal to convert the processed image signal into image data that is capable of being displayed on the electronic panel EP. The audio input module AIM receives external audio signals by a microphone during recording mode or a voice recognition mode to convert the received audio signal into electrical sound data.

The external interface IF serves as an interface connected to an external charger, a wired/wireless data port, and a card socket (e.g., a memory card and a subscriber identity module/user identity module (“SIM/UIM”) card).

The second electronic module EM2 may include an audio output module AOM, a light-emitting module LM, a light-receiving module LRM, and a camera module CMM. The above-described constituents may be directly disposed (e.g., mounted) on the mother board, may be disposed (e.g., mounted) on a separate board and electrically connected to the electronic panel EP through a connector (not shown), or may be electrically connected to the first electronic module EM1.

The audio output module AOM converts audio data received from the wireless communication module TM or audio data stored in the memory MM to output the converted audio data to the outside.

The light-emitting module LM generates and outputs light. The light-emitting module LM may output infrared rays. The light-emitting module LM may include a light-emitting diode (“LED”). The light-receiving module LRM may sense the infrared rays. The light-receiving module LRM may be activated when infrared rays having a predetermined level or more is sensed. The light-receiving module LRM may include a complementary metal-oxide-semiconductor (“CMOS”) sensor. The infrared rays generated in the light-emitting module LM may be outputted and then be reflected by an external object (e.g., a user's finger or face), and the reflected infrared rays may be incident into the light-receiving module LRM. The camera module CMM photographs an external image.

The electronic module 400 in an embodiment of the inventive concept may include at least one of constituents of the second electronic module EM2. In an embodiment, the electronic module 400 may include at least one of a camera, a speaker, an optical detection sensor, or a thermal detection sensor, for example. The electronic module 400 may sense an external object received through the hole area A1 or provide a sound signal such as a voice to the outside through the hole area A1. Also, the electronic module 400 may include a plurality of constituents, but is not limited to an illustrative embodiment. Although not shown, the electronic module 400 may be attached to the electronic panel EP using a separate adhesive.

FIG. 4 illustrates a portion XX′ of the active area AA next (adjacent) to the module hole MH in the display panel DP (refer to FIG. 3).

Referring to FIG. 4, most of the pixels PX included in the display panel DP may be disposed on a pixel area A2, and some of the pixels PX may be disposed on the pixel area A2 along a boundary between the hole area A1 and the pixel area A2 and spaced apart from the hole area A1.

The module hole MH may be defined within the active area AA. Thus, at least some of the pixels PX may be disposed next (adjacent) to the module hole MH and spaced apart from each other with the module hole MH therebetween.

At least one dam pattern DMP may be disposed on the hole area A1 of the display panel DP. The electronic device 1000 (refer to FIG. 2) in an embodiment may block a path through which moisture and/or oxygen are introduced from the module hole MH to the pixels PX by the dam pattern DMP. In addition, during a process of forming the module hole MH, an etchant may be prevented from being introduced into the display panel DP through the module hole MH. Thus, the display panel DP having improved quality may be provided. A detailed description of the dam pattern DMP will be provided later.

The dam pattern DMP may be disposed on the hole area A1 and surround at least a portion of the module hole MH. On a plane, the dam pattern DMP may have a closed-line shape surrounding the module hole MH.

In an embodiment, a filler may be disposed inside the module hole MH. The filler may include a polymer resin. As the filler is disposed inside the module hole MH, a flat surface may be provided on the constituents disposed on the module hole MH.

A portion of each of signal lines SGL1 and SGL2 connected to the pixels PX may be disposed on the hole area A1. The signal lines SGL1 and SGL2 may be connected to the pixels PX, which are spaced apart from each other with the module hole MH therebetween via the hole area A1. For ease of explanation, FIG. 4 illustrates two signal lines SGL1 and SGL2 of a plurality of signal lines connected to the pixels PX.

The first signal line SGL1 may extend in the first direction DR1. The first signal line SGL1 may be connected to the pixels within the same row arranged in the first direction DR1 of the pixels PX. In an embodiment, the first signal line SGL1 may correspond to one of scan lines connected to the pixels PX, for example.

A portion of the pixels PX connected to the first signal line SGL1 may be disposed at a left side of the module hole MH, and a remaining (the other) portion of the pixels PX may be disposed at a right side of the module hole MH. Thus, the pixels in the same row connected to the first signal line SGL1 may be turned on/off by substantially the same scan signal even though a portion of the pixels with respect to the module hole MH is omitted.

The second signal line SGL2 may extend in the second direction DR2. The second signal line SGL2 may be connected to the pixels in the same column arranged in the second direction DR2 in the pixels PX. In an embodiment, the second signal line SGL2 may correspond to one of the data lines connected to the pixels PX, for example.

A portion of the pixels PX connected to the second signal line SGL2 may be disposed above the module hole MH, and a remaining (the other) portion of the pixels PX may be disposed below the module hole MH. Thus, the pixels in the same row connected to the second signal line SGL2 may receive a data signal through the same line even though a portion of the pixels with respect to the module hole MH is omitted.

At least one of the first signal line SGL1 or the second signal line SGL2 may be disconnected within the hole area A1 at a point at which the first signal line SGL1 and the second signal line SGL2 intersect. Thus, a connection pattern disposed in a layer different from that of the disconnected signal line to connect the disconnected portions may be further provided. However, a connection relationship between the pixels PX spaced apart from each other with the module hole MH therebetween is not limited thereto.

FIG. 5 is a cross-sectional view taken along line I-I′ of FIG. 2. In FIG. 5, the housing 200 described in FIG. 1 may be omitted. FIG. 5 illustrates a cross-section of the electronic device 1000 corresponding to the pixel PX described in FIG. 2.

Referring to FIG. 5, the electronic device 1000 in an embodiment may include a display module 100, a cover organic layer IJP, an anti-reflection layer ARL, the housing 200 described in FIG. 2, and a window 300. The display module 100 may include a display panel DP and an input sensor ISL.

The pixel PX described in FIG. 2 may include a light-emitting element LD and a pixel driving circuit. The pixel driving circuit may include a plurality of transistors and a capacitor. FIG. 5 illustrates two transistors T1 and T2 included in the pixel PX described in FIG. 2 as an example. In an embodiment, the transistors included in the pixel PX (refer to FIG. 2) may be oxide semiconductors. In an embodiment, each of the transistors may include a semiconductor layer including metal oxide, for example. However, the configuration of the pixel driving circuit is not necessarily limited thereto. Some of the transistors included in the pixel driving circuit may include silicon transistors, and others may include oxide transistors.

The display module 100 in an embodiment may include a display panel DP and an input sensor ISL. The input sensor ISL may be disposed directly on the display panel DP. The cover organic layer IJP, the anti-reflection layer ARL, and the window 300 may be disposed on the display module 100.

The display panel DP may include a base layer 110, a circuit element layer 120, a display element layer 130, and an encapsulation layer 140.

The display panel DP may further include functional layers such as an anti-reflection layer and a refractive index adjustment layer. The circuit element layer 120 may include at least a plurality of insulating layers and circuit elements. Hereinafter, the insulating layers may include an organic layer and/or an inorganic layer.

An insulating layer, a semiconductor layer, and a conductive layer may be formed on the base layer 110 by coating, deposition, etc. Thereafter, the insulating layer, the semiconductor layer, and the conductive layer may be selectively patterned in a photolithography manner. In this manner, semiconductor patterns, conductive patterns, signal lines, etc. may be formed.

The base layer 110 may be a base layer on which other components of the circuit element layer 120 are disposed. The base layer 110 may have a structure in which layers including or consisting of organic materials and layers including or consisting of inorganic materials are alternately laminated. In an embodiment, in this embodiment, the base layer 110 may include a first organic layer PI1, a first inorganic layer BA1, a second organic layer PI2, and a second inorganic layer BA2, which are sequentially laminated, for example.

The first organic layer PI1 may be disposed at the lowermost side. The first organic layer PI1 may include an organic material. In an embodiment, the first organic layer PI1 may include at least one of polyimide (“PI”), polyethylene naphthalate (“PEN”), polyethylene terephthalate (“PET”), polyarylate, polycarbonate (“PC”), polyetherimide (“PEI”), or polyethersulfone (“PES”), for example.

The first inorganic layer BA1 may be disposed on the first organic layer PI1. The first inorganic layer BA1 may include an inorganic material. In an embodiment, the first inorganic layer BA1 may include at least one of silicon oxide, silicon oxynitride, aluminum oxide, titanium oxide, silicon nitride, zirconium oxide, hafnium oxide, or amorphous silicon, for example.

The second organic layer PI2 may be disposed on the first inorganic layer BA1. The second organic layer PI2 may include an organic material. The organic material included in the second organic layer PI2 may be the same as the organic material included in the first base layer BI1.

The second inorganic layer BA2 may be disposed on the first organic layer PI1. The second inorganic layer BA2 may include an inorganic material. The inorganic material included in the second inorganic layer BA2 may be the same as the inorganic material included in the first inorganic layer BA1. The second inorganic layer BA2 may correspond to a barrier layer.

However, this embodiment is not limited thereto, and the base layer 110 may be provided as a single layer. Here, the base layer 110 may include a synthetic resin film. The synthetic resin layer may include a thermosetting resin. Particularly, the synthetic resin layer may be a polyimide resin layer, and the material thereof is not particularly limited. In addition, the base layer 110 may include glass, a metal, or an organic/inorganic composite material.

According to this embodiment, a light-blocking pattern BMI disposed inside the second inorganic layer BA2 may be further provided. The light-blocking pattern BMI may overlap a first semiconductor pattern included in a first transistor T1. In addition, the light-blocking pattern BMI may overlap a second semiconductor pattern included in a second transistor T2. The light-blocking pattern BMI may include a metal. In an embodiment, the light-blocking pattern BMI may include molybdenum (Mo), for example.

The first insulating layer 10 may be disposed on the second inorganic layer BA2 of the base layer 110. The first insulating layer 10 may correspond to a buffer layer. The first insulating layer 10 may include a silicon oxide layer and a silicon nitride layer. In addition, a silicon oxynitrite layer may have a single-layer or multi-layer structure, but is not limited to any embodiment.

The first semiconductor pattern of the first transistor T1 may be disposed on the first insulating layer 10. FIG. 5 illustrates only a portion of the first semiconductor pattern, and the first semiconductor pattern may be further disposed on other areas of the pixel PX (refer to FIG. 4). The first semiconductor pattern may have different electrical properties depending on whether the first semiconductor pattern is doped. The first semiconductor pattern may include a doped region and an undoped region. The doped region may be doped with an N-type dopant or a P-type dopant. A P-type transistor includes a doped region into which the P-type dopant is doped.

The source S1, an active AT1, and a drain D1 of the first transistor T1 may be formed from the first semiconductor pattern. The source S1 and the drain D1 of the first transistor T1 may be spaced apart from each other with the active AT1 therebetween.

A connection signal line SCL may be disposed on the first insulating layer 10. The connection signal line SCL may be connected to any one of the plurality of transistors included in the pixel PX (refer to FIG. 4).

The second insulating layer 20 may cover the first semiconductor pattern and the connection signal line SCL and may be disposed on the first insulating layer 10. The second insulating layer 20 may include an inorganic layer and/or an organic layer and have a single-layer or multi-layered structure. The second insulating layer 20 may include at least one of aluminum oxide, titanium oxide, silicon oxide, silicon oxynitride, zirconium oxide, or hafnium oxide. In this embodiment, the second insulating layer 20 may be provided as an inorganic layer.

A gate GE1 of the first transistor T1 may be disposed on the second insulating layer 20. The gate GE1 may be a portion of a metal pattern. The gate GE1 of the first transistor T1 may overlap the active AT1 of the first transistor T1. In a process of doping the first semiconductor pattern, the gate GE1 of the first transistor T1 may serve as a mask.

A third insulating layer 30 covering the gate GE1 may be disposed on the second insulating layer 20. The third insulating layer 30 may include an inorganic layer and/or an organic layer and have a single-layer or multi-layered structure. In this embodiment, the third insulating layer 30 may include an inorganic layer and/or an organic layer and have a single-layer or multi-layered structure. In this embodiment, the second insulating layer 20 may be provided as an inorganic layer.

An upper electrode UE may be disposed on the third insulating layer 30. The upper electrode UE may overlap the gate GE1. The upper electrode UE may be a portion of the metal pattern or the doped semiconductor pattern. A portion of the gate GE1 and the upper electrode UE overlapping the portion of the gate GE1 may define a capacitor included in the pixel PX. In an embodiment of the inventive concept, the upper electrode UE may be omitted.

A fourth-first insulating layer 40-1 covering the upper electrode UE may be disposed on the third insulating layer 30. In this embodiment, the fourth insulating layer 40 may include at least one silicon oxide layer and at least one silicon nitride layer, which are alternately laminated.

The second semiconductor pattern of the second transistor T2 may be disposed on the third insulating layer 30. The second semiconductor pattern may include metal oxide. Oxide semiconductors may include crystalline or amorphous oxide semiconductors.

In an embodiment, oxide semiconductors may include metal oxides such as zinc (Zn), indium (In), gallium (Ga), tin (Sn), and titanium (Ti), or metals such as zinc (Zn), indium (In), and gallium (Ga), tin (Sn), titanium (Ti), and combinations thereof, for example. The oxide semiconductors may include indium-tin oxide (“ITO”), indium-gallium-zinc oxide (“IGZO”), zinc oxide (ZnO), indium-zinc oxide (IZnO), zinc-indium oxide (“ZIO”), indium oxide (InO), titanium oxide (TiO), indium-zinc-tin oxide (“IZTO”), zinc-tin oxide (“ZTO”), etc.

A source S2, an active AT2, and a drain D2 of the second transistor T2 may be formed from the second semiconductor pattern. Each of the source S2 and the drain D2 may include a metal reduced from a metal oxide semiconductor. Each of the source S2 and the drain D2 may have a predetermined thickness from a top surface of the second semiconductor pattern and may include a metal layer including the reduced metal.

A fourth-second insulating layer 40-2 covering the second semiconductor pattern may be disposed on the third insulating layer 30. In this embodiment, the fourth-second insulating layer 40-2 may be single layered silicon oxide. In the description, the fourth-first insulating layer 40-1 and the fourth-second insulating layer 40-2 may be collectively referred to as a fourth insulating layer 40.

The gate GE2 of the second transistor T2 may be disposed on the fourth insulating layer 40. The gate GE2 may be a portion of a metal pattern. The gate GE2 of the second transistor T2 may overlap the active AT2 of the second transistor T2.

A fifth insulating layer 50 covering the gate GE2 may be disposed on the fourth insulating layer 40. In this embodiment, the fifth insulating layer 50 may include at least one silicon oxide layer and at least one silicon nitride layer, which are alternately laminated.

At least one insulating layer may be further disposed on a fifth insulating layer 50. As in this embodiment, a sixth insulating layer 60 and a seventh insulating layer 70 may be disposed on the fifth insulating layer 50. Each of the sixth insulating layer 60 and the seventh insulating layer 70 may be an organic layer and may have a single-layer or multi-layer structure. Each of the sixth insulating layer 60 and the seventh insulating layer 70 may be a single-layered polyimide-based resin layer.

However, this embodiment is not limited thereto. In an embodiment, each of the sixth insulating layer 60 and the seventh insulating layer 70 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin, for example.

A first connection electrode CNE1 may be disposed on the fifth insulating layer 50. The first connection electrode CNE1 may be connected to the connection signal line SCL through a first contact hole passing through a portion of the second to fifth insulating layers 20 to 50.

A second connection electrode CNE2 may be disposed on the sixth insulating layer 60. The second connection electrode CNE2 may be connected to the first connection electrode CNE1 through a second contact hole passing through the sixth insulating layer 60.

A light-emitting element LD may be disposed on the seventh insulating layer 70. The first electrode AE of the light-emitting element LD may be disposed on the seventh insulating layer 70. A pixel defining layer PDL is disposed on the seventh insulating layer 70. The pixel defining layer PDL may define a display opening that exposes at least a portion of the first electrode AE. In this embodiment, the pixel defining layer PDL may include a light-absorbing material. In an embodiment, the pixel defining layer PDL may have a black color, for example.

A spacer SPC may be disposed on the pixel defining layer PDL. The spacer SPC may prevent the pixel defining layer PDL having a black component from being visibly recognized to the outside, and a groove for fixing a support that supports a mask in a process of forming the light-emitting pattern EL through the deposition process may be defined in the spacer SPC. The groove may be defined by penetrating at least a portion of the spacer SPC. The spacer SPC may be an organic layer including polyimide. The spacer SPC in an embodiment may be transparent. A spacer opening that exposes a portion of the first electrode AE and overlaps the display opening may be defined in the spacer SPC. An emission area LA may be defined to correspond to the spacer opening.

The light-emitting pattern EL may be disposed inside the spacer opening and may be disposed on the first electrode AE. In an embodiment of the inventive concept, a hole control layer may be disposed between the first electrode AE and the light-emitting pattern EL. The hole control layer may include a hole transport layer and may further include a hole injection layer. An electronic control layer may be disposed between the light-emitting pattern EL and the second electrode CE. The electronic control layer includes an electron transport layer and may further include an electron injection layer.

The second electrode CE may be disposed on the light-emitting pattern EL. The electronic control layer may be disposed between the light-emitting pattern EL and the second electrode CE. The electron control layer may include an electron transport layer and an electron injection layer. The second electrode CE may be disposed on the light-emitting pattern EL. The electron control layer, the hole control layer, and the second electrode CE may be commonly disposed on the plurality of pixels PX (refer to FIG. 4).

An encapsulation layer 140 may cover the light-emitting element LD. The encapsulation layer 140 may include a first encapsulation inorganic layer 141, an organic encapsulation layer 142, and a second encapsulation inorganic layer 143, which are sequentially laminated. However, the layers constituting the encapsulation layer 140 are not necessarily limited thereto. Each of the encapsulation inorganic layers 141 and 143 may include a silicon nitride layer, a silicon oxynitride layer, a silicon oxide layer, a titanium oxide layer, or an aluminum oxide layer. Each of the encapsulation inorganic layers 141 and 143 may have a multilayer structure. The encapsulation organic layer 142 may include an acrylic-based organic layer, but is not limited thereto.

The input sensor ISL may include at least one conductive layer (or at least one sensor conductive layer) including conductive patterns and at least one sensing insulating layer (or at least one sensor insulating layer).

In this embodiment, the input sensor ISL may include a first sensing insulating layer 210, first conductive patterns TML1, a second sensing insulating layer 220, second conductive patterns TML2, a third sensing conductive layer 230, and a fourth sensing insulating layer 240. FIG. 5 illustrates the first conductive patterns TML1 included in the first conductive layer and the second conductive patterns TML2 included in the second conductive layer as an example.

The first sensing insulating layer 210 may be directly disposed on the display panel DP. That is, the first sensing insulating layer 210 may contact the second encapsulating inorganic layer 143. The first sensing insulating layer 210 may be an inorganic layer including at least one of silicon nitride, silicon oxynitride, or silicon oxide.

The first conductive patterns TML1 may be disposed on the first sensing insulating layer 210. The second conductive patterns TML2 may be disposed on the second sensing insulating layer 220. Each of the first conductive patterns TML1 and the second conductive patterns TML2 may have a single-layer structure or a sequentially laminated multi-layer structure. The second conductive patterns TML2 may include conductive lines defining mesh-shaped electrodes. The conductive lines of the second conductive patterns TML2 and the first conductive patterns TML1 may or may not be connected to each other through a contact hole passing through the second sensing insulating layer 220. A connection relationship between the conductive lines of the first conductive patterns TML1 and the second conductive patterns TML2 may be determined depending on the type of sensor forming the input sensor ISL.

The first conductive patterns TML1 and the second conductive patterns TML2, each of which has the single-layer structure, may include a metal layer or a transparent conductive layer. The metal layer may include molybdenum, silver, titanium, copper, aluminum, or any alloys thereof. The transparent conductive layer may include a transparent conductive oxide such as ITO, IZO, zinc oxide (ZnOx), or IZTO. In addition, the transparent conductive layer may include a conductive polymer such as poly(3,4-ethylenedioxythiophene) (“PEDOT”), a metal nanowire, graphene, etc.

The first conductive patterns TML1 and TML2 having the multilayer structure may include metal layers. The metal layers may have a 3-layer structure of titanium/aluminum/titanium. The multi-layered conductive layer may include at least one metal layer and at least one transparent conductive layer.

The second sensing insulating layer 220 may cover the first conductive patterns TML1 and may be disposed on the first sensing insulating layer 210. The second conductive patterns TML2 may be disposed on the second sensing insulating layer 220. The third sensing insulating layer 230 may cover the second conductive patterns TML2 and may be disposed on the second sensing insulating layer 220. Each of the second sensing insulating layer 220 and the third sensing insulating layer 230 may be an inorganic layer including at least one of silicon nitride, silicon oxynitride, or silicon oxide.

The fourth sensing insulating layer 240 may be disposed on the third sensing insulating layer 230. The fourth sensing insulating layer 240 may compensate for a height difference generated in the process of forming constituents disposed below the fourth sensing insulating layer 240. Thus, the fourth sensing insulating layer 240 may include an organic material.

The cover organic layer IJP may be disposed on the input sensor ISL. The cover organic layer IJP may compensate for a height difference generated during the process of forming the display panel DP and the input sensor ISL. Thus, a flat surface may be provided to the constituents disposed on the display panel DP. The cover organic layer IJP may include an organic material. The cover organic layer IJP may be formed on the fourth sensing insulating layer 240 by an inkjet process.

The display module 100 in an embodiment may further include an anti-reflection layer ARL. The anti-reflection layer ARL may be disposed between the cover organic layer IJP and the window 300. The anti-reflection layer ARL may reduce reflection of light incident from the outside of the electronic device 1000. That is, the anti-reflection layer ARL may reduce external light reflectance of the electronic device 1000. The anti-reflection layer ARL in an embodiment may include a polarizing layer, a phasor, a destructive interference structure, or a plurality of color filters.

A first adhesive layer AD1 may be disposed between the anti-reflection layer ARL and the cover organic layer IJP to couple the anti-reflection layer ARL to the cover organic layer IJP. The first adhesive layer AD1 may include at least one of an optically clear adhesive, an optically clear adhesive resin, or a pressure sensitive adhesive PSA.

The window 300 may be disposed on the anti-reflection layer ARL. A second adhesive layer AD2 may be disposed between the anti-reflection layer ARL and the window 300 to couple the anti-reflection layer ARL to the window 300. The second adhesive layer AD2 may include the same material as that of the first adhesive layer AD1.

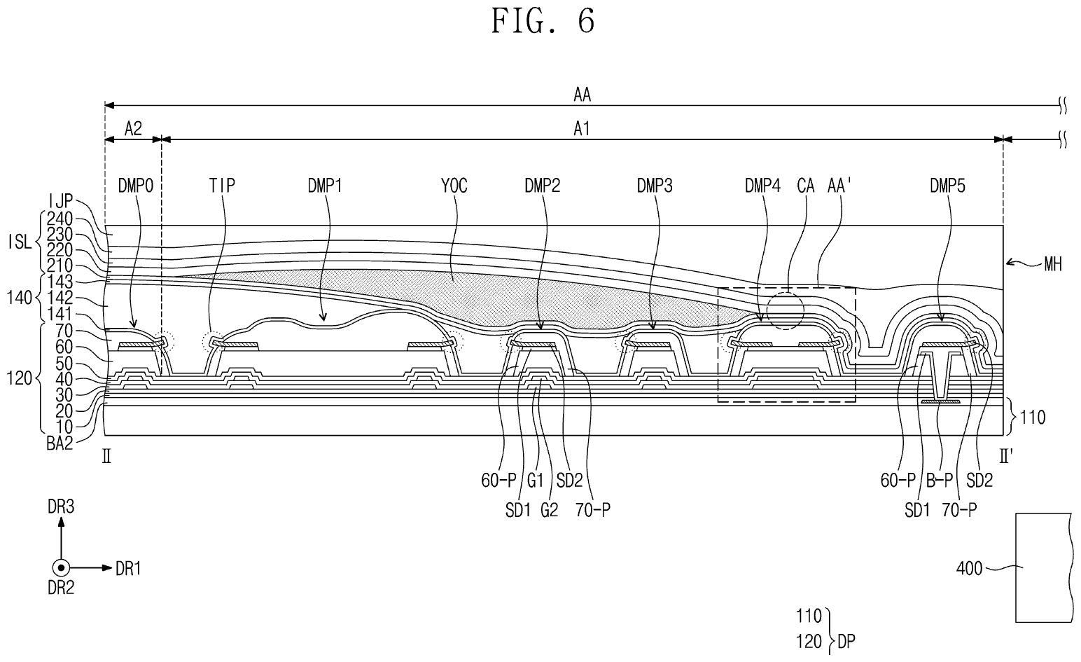

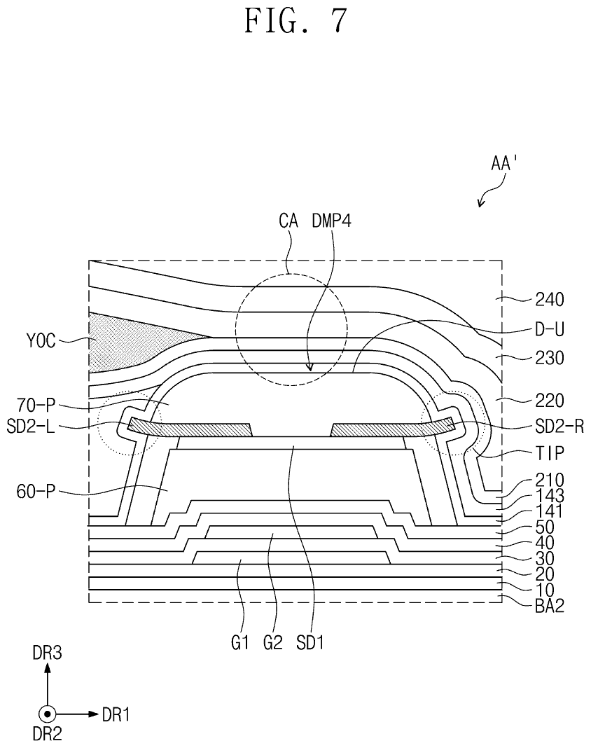

FIG. 6 is a cross-sectional view of the electronic device, taken along line II-II′ of FIG. 2. FIG. 7 is an enlarged cross-sectional view of an area AA′ of FIG. 6. FIG. 6 illustrates a cross-sectional view of a hole area A1 in the active area AA and a pixel area A2 next (adjacent) to the hole area A1.

The electronic device 1000 in an embodiment may have a display panel DP overlapping the hole area A1, an input sensor ISL, and a module hole MH which passes through the cover organic layer IJP. The module hole MH may overlap the electronic module 400. Particularly, the module hole MH may overlap a camera module CMM (refer to FIG. 3) of the electronic module 400.

At least one of the first adhesive layer AD1, the anti-reflection layer ARL, the second adhesive layer AD2, and the window 300 described in FIG. 5 may cover the module hole MH to prevent a side surface of each of the display panel DP, the input sensor ISL, and the cover organic layer IJP, which define the module hole MH, from being exposed to the outside. In an embodiment, a resin layer disposed inside the module hole MH may be further provided.

The active area AA of the display panel DP may include a hole area A1 and a pixel area A2. In this specification, the hole area A1 and the pixel area A2 may be defined in the base layer 110. The hole area A1 may be defined as an area overlapping the electronic module 400, and the pixel area A2 may surround at least a portion of the hole area A1 within the active area AA. The pixel area A2 may be an area on which the pixels PX described in FIG. 2 are disposed.

The display panel DP may include first to fifth dam patterns DMP1 to DMP5 disposed on the hole area A1. The first to fifth dam patterns DMP1 to DMP5 may be sequentially arranged in a direction from the pixel area A2 toward the module hole MH. On the plane, each of the first to fifth dam patterns DMP1 to DMP5 may have a closed-line shape surrounding the module hole HM.

As illustrated in FIG. 7, each of the first to fifth dam patterns DMP1 to DMP5 may include a first insulating pattern 60-P, a second insulating pattern 70-P, a first pattern SD1, and a second pattern SD2. The first pattern SD1 and the second pattern SD2 may contact each other.

Each of the first insulating pattern 60-P and the second insulating pattern 70-P may include an organic material. The first insulating pattern 60-P may be a portion that is patterned from the sixth insulating layer 60 described in FIG. 5, and the second insulating pattern 70-P may be a portion patterned from the seventh insulating layer 70 described in FIG. 5. Thus, the first insulating pattern 60-P may be disposed on the fifth insulating layer 50.

The first pattern SD1 may be formed through the same process as the first connection electrode CNE1 described in FIG. 4 and may include the same material as that of the first connection electrode CNE1. The second pattern SD2 may be formed through the same process as the second connection electrode CNE2 described in FIG. 4 and may include the same material as that of the second connection electrode CNE2. Each of the first pattern SD1 and the second pattern SD2 may include first, second, and third layers, which are sequentially laminated, each of the first and third layers may include titanium, and the second layer may include aluminum.

In an embodiment of the inventive concept, the second pattern SD2 included in each of the first to fifth dam patterns DMP1 to DMP5 may protrude from a side surface of the first insulating pattern 60-P and a side surface of the second insulating pattern 70-P to define a tip part TIP. At least two tip parts TIP included in the next (adjacent) dam patterns of the first to fifth dam patterns DMP1 to DMP5 may face each other.

According to this embodiment, the first to fifth dam patterns DMP1 to DMP5 may be covered by the first encapsulation inorganic layer 141. Thus, the second pattern SD2 defining the tip part TIP of each of the first to fifth dam patterns DMP1 to DMP5 may also be covered by the first encapsulation inorganic layer 141.

The first dam pattern DMP1 may include two first patterns SD1 disposed on the first insulating pattern 60-P and spaced apart from each other, and second patterns SD2 that contact the first patterns SD1, respectively. The second patterns SD2 may protrude from side surfaces of the first and second insulating patterns 60-P and 70-P to define two tip parts TIP.

In an embodiment, a sub-dam pattern DMP0 next (adjacent) to a boundary between the pixel area A2 and the hole area A1 and disposed at an end of the pixel area A2 may be further provided. The sub-dam pattern DMP0 may include a first pattern SD1 disposed at an end of the sixth insulating layer 60 and a second pattern SD2 that contacts the first pattern SD1. The second pattern SD2 may be covered by the seventh insulating layer 70. The second pattern SD2 of the sub-dam pattern DMP0 may protrude from between the sixth insulating layer 60 and the seventh insulating layer 70 to define a tip part TIP.

In this embodiment, the tip part TIP of the sub-dam pattern DMP0 and the tip part TIP of any one of the first dam patterns DMP1 may face each other.

The tip part TIP of the second dam pattern DMP2 may protrude to a left side in the cross-section, and the tip part TIP of a remaining (the other) one of the first dam patterns DMP1 may face each other.

The tip part TIP of the third dam pattern DMP3 may protrude to a left side in the cross-section.

The fourth dam pattern DMP4 may include two second patterns SD2-L and SD2-R disposed on the first pattern SD1 and spaced apart from each other, as illustrated in FIG. 6. A 2-1 pattern SD2-L may protrude to a left side of the fourth dam pattern DMP4 in the cross-section, and a 2-2 pattern SD2-R may protrude to a right side of the fourth dam pattern DMP4 in the cross-section. Thus, two tip parts TIP may be defined on the fourth dam pattern DMP4. The tip part TIP defined as the 2-1 pattern SD2-L may protrude toward the third dam pattern DMP3. The tip part TIP defined by the 2-2 pattern SD2-R may protrude toward the fifth dam pattern DMP5.

The tip part TIP of the fifth dam pattern DMP5 may protrude in a direction toward the module hole MH.

However, the shape and number of the first to fifth dam patterns DMP1 to DMP5 illustrated in FIG. 6 are not limited thereto, and the protruding direction of the tip parts included in each of the first to fifth dam patterns DMP1 to DMP5 may also not be limited thereto.

According to this embodiment, each of the first to fourth dam patterns DMP1 to DMP4 may further include a first dummy pattern G1 and a second dummy pattern G2. The first dummy pattern G1 may be disposed on the second insulating layer 20 and buckled by the third insulating layer 30. The second dummy pattern G2 may overlap the first dummy pattern G1, be disposed on the third insulating layer 30, and be covered by the fourth insulating layer 40. The first dummy pattern G1 may be formed through the same process as the first gate GE1 of the first transistor T1 described in FIG. 5 and may include the same material as that of the first gate GE1. The second dummy pattern G2 may be formed through the same process as the second gate GE2 of the second transistor T2 described in FIG. 5 and may include the same material as that of the second gate GE2. As the first to fourth dam patterns DMP1 to DMP4 include the first dummy pattern G1 and the second dummy pattern G2, a height of each of the dam patterns may be adjusted.

The fifth dam pattern DMP5 may further include a dummy pattern B-P. The dummy pattern B-P may be disposed inside the second inorganic layer BA2 of the base layer 110 described in FIG. 5. The first pattern SD1 of the fifth dam pattern DMP5 may overlap the dummy pattern B-P through a portion of the second inorganic layer BA2 overlapping the dummy pattern B-P, the first to fifth insulating layers 10 to 50, and the contact hole passing through the first insulating pattern 60-P.

The input sensor ISL in an embodiment of the inventive concept may include an organic pattern layer YOC. The organic pattern layer YOC may overlap the hole area A1 and be disposed between the first sensing insulating layer 210 and the second sensing insulating layer 220. The organic pattern layer YOC may compensate for a height difference generated in the process of manufacturing the first to fifth dam patterns DMP1 to DMP5.

According to this embodiment, the organic pattern layer YOC may be disposed from the groove defined between the first and second dam patterns DMP1 and DMP2 to the fourth dam pattern DMP4. According to this embodiment, a boundary of the organic pattern layer YOC within the hole area A1 may be defined by the fourth dam pattern DMP4.

The electronic device 1000, in which a module hole MH is defined in the active area AA as in the inventive concept, may provide a path through which the moisture and/or oxygen introduced from the module hole MH are introduced into the light-emitting element LD (refer to FIG. 5) along the organic material disposed on the hole area A1. In an embodiment of the inventive concept, a boundary of the organic pattern layer YOC may be defined by the fourth dam pattern DMP4, and as illustrated in FIG. 6, a top surface D-U of the fourth dam pattern DMP4 may be exposed from the organic pattern layer YOC. Thus, the second encapsulation inorganic layer 143, the first sensing insulating layer 210, the second sensing insulating layer 220, and the third sensing insulating layer 230, each of which include the inorganic material, may contact each other on the top surface D-U of the fourth dam pattern DMP4. In addition, the first encapsulation inorganic layer 141 may contact the second encapsulation inorganic layer 143 on the top surface D-U of the fourth dam pattern DMP4.

In this specification, an area on which the second encapsulation inorganic layer 143, the first sensing insulating layer 210, the second sensing insulating layer 220, and the third sensing insulating layer 230 are in contact with each other may be defined as a ‘bonding area CA’ on any one top surface.

According to this embodiment, the path through which the moisture and/or oxygen introduced from the module hole MH are introduced into the light-emitting element LD (refer to FIG. 5) may be blocked by the bonding area CA. Thus, the electronic device 1000 including the light-emitting element LD (refer to FIG. 5) having improved lifespan and reliability may be provided.

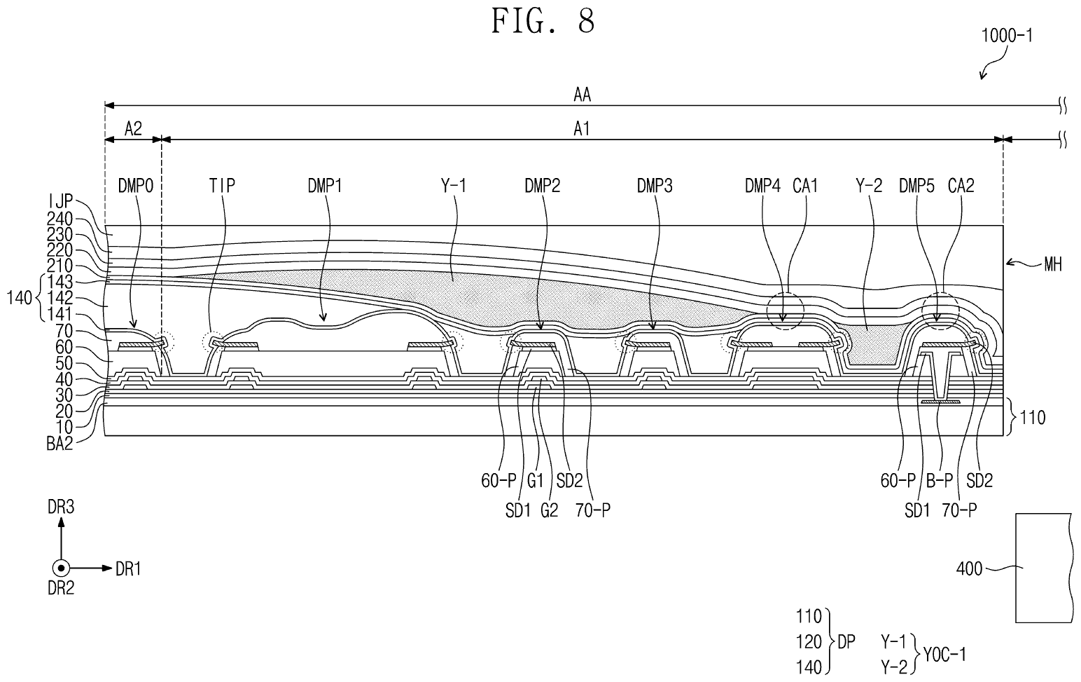

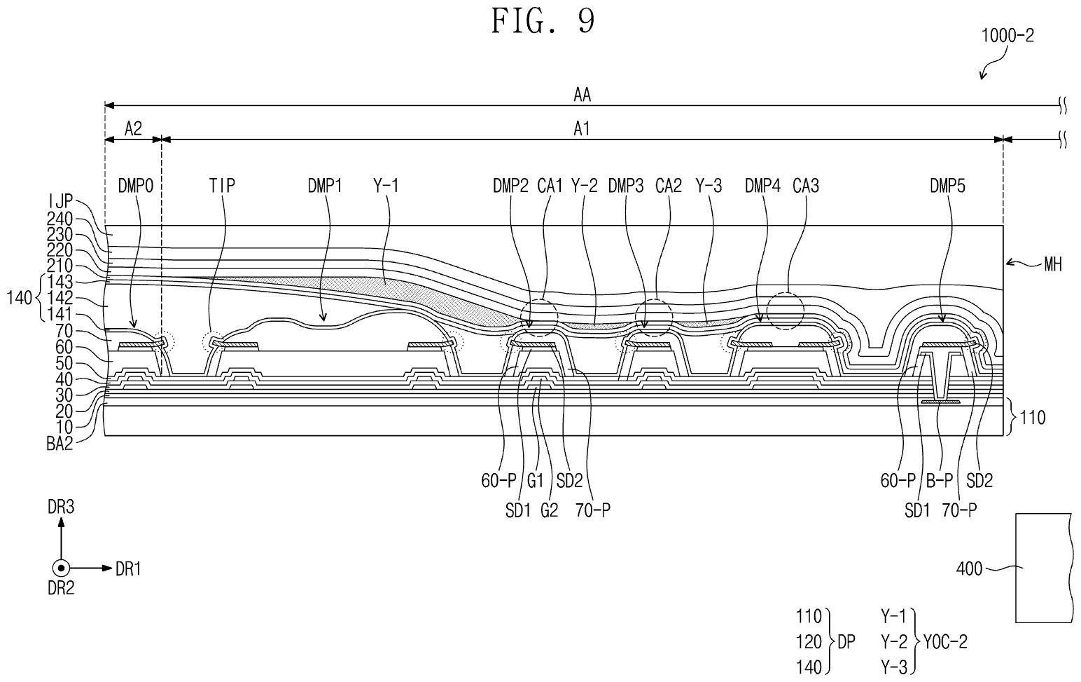

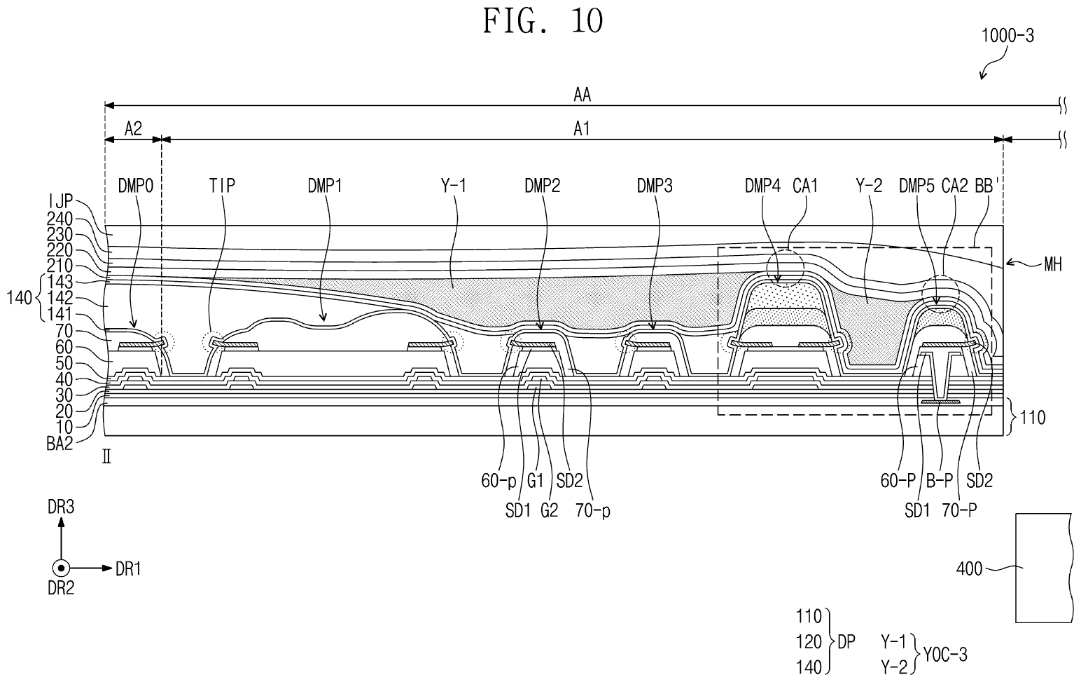

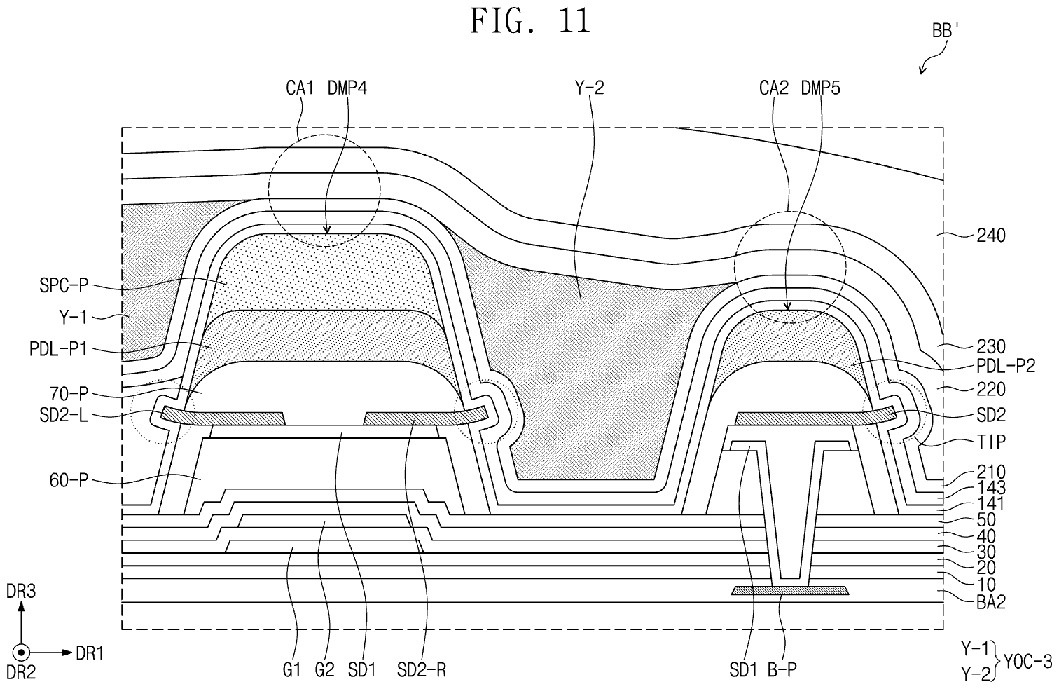

FIG. 8 is a cross-sectional view of an embodiment of an electronic device according to the inventive concept. FIG. 9 is a cross-sectional view of an embodiment of an electronic device according to the inventive concept. FIG. 10 is a cross-sectional view of an embodiment of an electronic device according to the inventive concept. FIG. 11 is an enlarged cross-sectional view of an area BB′ of FIG. 10. The same/similar reference numerals are used for components that are the same/similar to those described in FIGS. 1 to 7, and duplicate descriptions are omitted.

Electronic devices 1000-1, 1000-2, and 1000-3 described in FIGS. 8 to 10 illustrate only a display panel DP and an input sensor ISL, which are included in the display module 100 (refer to FIG. 2), and constituents disposed on the display module 100 (refer to FIG. 2) will be omitted.

Referring to FIG. 8, the electronic device 1000-1 in an embodiment may include a display panel DP and an input sensor ISL. The display panel DP may include a base layer 110, a circuit element layer 120, a display element layer 130, and an encapsulation layer 140. The display panel DP may include first to fifth dam patterns DMP1 to DMP5 disposed on a hole area A1. The first to fifth dam patterns DMP1 to DMP5 may be sequentially arranged in a direction from the pixel area A2 toward a module hole MH. On the plane, each of the first to fifth dam patterns DMP1 to DMP5 may have a closed-line shape surrounding the module hole HM.

The input sensor ISL may include a first sensing insulating layer 210, first conductive patterns TML1, a second sensing insulating layer 220, second conductive patterns TML2, a third sensing conductive layer 230, and a fourth sensing insulating layer 240.

The input sensor ISL in this embodiment may include an organic pattern layer YOC-1. The organic pattern layer YOC-1 may overlap the hole area A1 and be disposed between the first sensing insulating layer 210 and the second sensing insulating layer 220. The organic pattern layer YOC-1 may compensate for a height difference generated in the process of manufacturing the first to fifth dam patterns DMP1 to DMP5.

According to this embodiment, the organic pattern layer YOC-1 may be disposed from a groove defined between the first and second dam patterns DMP1 and DMP2 to the fifth dam pattern DMP5. According to this embodiment, a boundary of the organic pattern layer YOC-1 within the hole area A1 may be defined by the fifth dam pattern DMP5.

The organic pattern layer YOC-1 may include a first pattern Y-1 overlapping from the first dam pattern DMP1 to the fourth dam pattern DMP4 and a second pattern Y-2 disposed between the fourth dam pattern DMP4 and the fifth dam pattern DMP5. The first pattern Y-1 and the second pattern Y-2 may be portions that are short-circuited by the fourth dam pattern DMP4 in the process of forming the organic pattern layer YOC-1 by applying an organic material.

A top surface of the fourth dam pattern DMP4 maybe exposed between the first pattern Y-1 and the second pattern Y-2, and a top surface of the fifth dam pattern DMP5 may be exposed from the second pattern Y-2. According to this embodiment, a second encapsulation inorganic layer 143, a first sensing insulating layer 210, a second sensing insulating layer 220, and a third sensing insulating layer may contact each other on the top surface of the fourth dam pattern DMP4. In addition, the first encapsulation inorganic layer 141 and the second encapsulation inorganic layer 143 may contact each other on the top surface of the fourth dam pattern DMP4. Thus, a first bonding area CA1 may be defined on the top surface of the fourth dam pattern DMP4.

In addition, a second encapsulation inorganic layer 143, a first sensing insulating layer 210, a second sensing insulating layer 220, and a third sensing insulating layer 230 may contact each other on the top surface of the fifth dam pattern DMP5. In addition, the first encapsulation inorganic layer 141 and the second encapsulation inorganic layer 143 may contact each other on the top surface of the fifth dam pattern DMP5. Thus, a second bonding area CA2 may be defined on the top surface of the fifth dam pattern DMP5.

According to this embodiment, even when the organic pattern layer YOC-1 including an organic material is disposed between the fourth dam pattern DMP4 and the fifth dam pattern DMP5, a path through which moisture and/or oxygen are introduced from the module hole MH to the pixels PX (refer to FIG. 4) may be easily blocked through the first bonding area CA1 and the second bonding area CA2.

Referring to FIG. 9, the electronic device 1000-2 in an embodiment may include a display panel DP and an input sensor ISL. The display panel DP may include a base layer 110, a circuit element layer 120, a display element layer 130, and an encapsulation layer 140. The display panel DP may include first to fifth dam patterns DMP1 to DMP5 disposed on a hole area A1. The first to fifth dam patterns DMP1 to DMP5 may be sequentially arranged in a direction from the pixel area A2 toward a module hole MH. On the plane, each of the first to fifth dam patterns DMP1 to DMP5 may have a closed-line shape surrounding the module hole HM.

The input sensor ISL may include a first sensing insulating layer 210, first conductive patterns TML1, a second sensing insulating layer 220, second conductive patterns TML2, a third sensing conductive layer 230, and a fourth sensing insulating layer 240.

The input sensor ISL in this embodiment may include an organic pattern layer YOC-2. The organic pattern layer YOC-2 may overlap the hole area A1 and be disposed between the first sensing insulating layer 210 and the second sensing insulating layer 220. The organic pattern layer YOC-2 may compensate for a height difference generated in the process of manufacturing the first to fifth dam patterns DMP1 to DMP5.

According to this embodiment, the organic pattern layer YOC-2 may be disposed from a groove defined between the first and second dam patterns DMP1 and DMP2 to the fourth dam pattern DMP4. According to this embodiment, a boundary of the organic pattern layer YOC-2 within the hole area A1 may be defined by the fourth dam pattern DMP4.

The organic pattern layer YOC-2 may include the first pattern Y-1 overlapping from the first dam pattern DMP1 to the second dam pattern DMP2, a second pattern Y-2 disposed between the second dam pattern DMP2 and the third dam pattern DMP3, and a third pattern Y-3 disposed between the third dam pattern DMP3 and the fourth dam pattern DMP4. The first patterns Y-1 to the third patterns Y-3 may be portions that are short-circuited by the second to fourth dam patterns DMP2 to DMP4 in the process of forming the organic pattern layer YOC-2 by applying an organic material.

A top surface of the second dam pattern DMP2 may be exposed between the first pattern Y-1 and the second pattern Y-2, a top surface of the third dam pattern DMP3 may be exposed between the second pattern Y-2 and the third pattern Y-3, and a top surface of the fourth dam pattern DMP4 may be exposed from the third pattern Y-3.

According to this embodiment, a second encapsulation inorganic layer 143, a first sensing insulating layer 210, a second sensing insulating layer 220, and a third sensing insulating layer 230 may contact each other on the top surface of each of the second to fourth dam patterns DMP2 to DMP4. In addition, a first encapsulation inorganic layer 141 and a second encapsulation inorganic layer 143 may contact each other on the top surfaces of the second to fourth dam patterns DMP2 to DMP4. Thus, a first bonding area CA1 may be defined on the top surface of the second dam pattern DMP2, a second bonding area CA2 may be defined on the top surface of the third dam pattern DMP3, and a third bonding area CA3 may be defined on the top surface of the fourth dam pattern DMP4.

According to this embodiment, the organic pattern layer YOC-2 including an organic material may be disposed in each groove region defined between the second to fourth dam patterns DMP2 to DMP4 to provide the first to third bonding areas CA1, CA2, and CA3. Thus, a path through which moisture and/or oxygen are introduced from the module hole MH to the pixels PX (refer to FIG. 4) may be easily blocked.

Referring to FIGS. 10 and 11, the electronic device 1000-3 in an embodiment may include a display panel DP and an input sensor ISL. The display panel DP may include a base layer 110, a circuit element layer 120, a display element layer 130, and an encapsulation layer 140. The display panel DP may include first to fifth dam patterns DMP1 to DMP5 disposed on a hole area A1. The first to fifth dam patterns DMP1 to DMP5 may be sequentially arranged in a direction from the pixel area A2 toward a module hole MH. On the plane, each of the first to fifth dam patterns DMP1 to DMP5 may have a closed-line shape surrounding the module hole HM.

The input sensor ISL may include a first sensing insulating layer 210, first conductive patterns TML1, a second sensing insulating layer 220, second conductive patterns TML2, a third sensing conductive layer 230, and a fourth sensing insulating layer 240.

The input sensor ISL in this embodiment may include an organic pattern layer YOC-3. The organic pattern layer YOC-3 may overlap the hole area A1 and be disposed between the first sensing insulating layer 210 and the second sensing insulating layer 220. The organic pattern layer YOC-3 may compensate for a height difference generated in the process of manufacturing the first to fifth dam patterns DMP1 to DMP5.

According to this embodiment, the organic pattern layer YOC-3 may be disposed from a groove defined between the first and second dam patterns DMP1 and DMP2 to the fifth dam pattern DMP5. According to this embodiment, a boundary of the organic pattern layer YOC-3 within the hole area A1 may be defined by the fifth dam pattern DMP5.

The organic pattern layer YOC-3 may include a first pattern Y-1 overlapping from the first dam pattern DMP1 to the fourth dam pattern DMP4 and a second pattern Y-2 disposed between the fourth dam pattern DMP4 and the fifth dam pattern DMP5.

A top surface of the fourth dam pattern DMP4 maybe exposed between the first pattern Y-1 and the second pattern Y-2, and a top surface of the fifth dam pattern DMP5 may be exposed from the second pattern Y-2.

As illustrated in FIG. 11, the fourth dam pattern DMP4 in an embodiment may include a first additional pattern PDL-P1 disposed on the second insulating pattern 70-P and a second additional pattern SPC-P disposed on the first additional pattern PDL-P1. Each of the first additional pattern PDL-P1 and the second additional pattern SPC-P may include an organic material. The fourth dam pattern DMP4 may include the first additional pattern PDL-P1 and the second additional pattern SPC-P to increase in thickness within the hole area A1. The first additional pattern PDL-P1 may be formed through the same process as the pixel defining layer PDL described in FIG. 5 and may include the same material as that of the pixel defining layer PDL. The second additional pattern SPC-P may be formed through the same process as the spacer SPC described in FIG. 5 and may include the same material as that of the spacer SPC.

The fifth dam pattern DMP5 may further include a third additional pattern PDL-P2 disposed on the second insulating pattern 70-P. The third additional pattern PDL-P2 may include an organic material. The fifth dam pattern DMP5 may include the third additional pattern PDL-P2 to increase in thickness within the hole area A1. The third additional pattern PDL-P2 may be formed through the same process as the pixel defining layer PDL described in FIG. 5 and may include the same material as that of the pixel defining layer PDL.

According to this embodiment, a second encapsulation inorganic layer 143, a first sensing insulating layer 210, a second sensing insulating layer 220, and a third sensing insulating layer may contact each other on the top surface of the fourth dam pattern DMP4. In addition, the first encapsulation inorganic layer 141 and the second encapsulation inorganic layer 143 may contact each other on the top surface of the fourth dam pattern DMP4. Thus, a first bonding area CA1 may be defined on the top surface of the fourth dam pattern DMP4.

In addition, a second encapsulation inorganic layer 143, a first sensing insulating layer 210, a second sensing insulating layer 220, and a third sensing insulating layer 230 may contact each other on the top surface of the fifth dam pattern DMP5. In addition, the first encapsulation inorganic layer 141 and the second encapsulation inorganic layer 143 may contact each other on the top surface of the fifth dam pattern DMP5. Thus, a second bonding area CA2 may be defined on the top surface of the fifth dam pattern DMP5.

According to this embodiment, even when the organic pattern layer YOC-3 including an organic material is disposed between the fourth dam pattern DMP4 and the fifth dam pattern DMP5, a path through which moisture and/or oxygen are introduced from the module hole MH to the pixels PX (refer to FIG. 4) may be easily blocked through the first bonding area CAL and the second bonding area CA2.

According to the embodiment of the inventive concept, as the insulating layers including the inorganic material are laminated on the dam around the module hole defined on the active area, the path through which oxygen and/or moisture are penetrated into the light-emitting element through the module hole may be easily blocked. Therefore, the electronic device having the improved reliability may be provided.

It will be apparent to those skilled in the art that various modifications and variations may be made in the inventive concept. Thus, it is intended that the disclosure covers the modifications and variations of this invention provided they come within the scope of the appended claims and their equivalents.

Hence, the real protective scope of the inventive concept shall be determined by the technical scope of the accompanying claims.

What is claimed is:

1. An electronic device comprising:
a display panel comprising:
a base layer comprising:
an active area which comprises a hole area; and
a pixel area surrounding the hole area;
light-emitting elements disposed on the pixel area;
an encapsulation layer covering the light-emitting elements and comprising:
a first encapsulation inorganic layer;
an encapsulation organic layer; and
a second encapsulation inorganic layer; and
dam patterns disposed on the hole area;
an input sensor which are disposed on the encapsulation layer and comprising:
a first sensing insulating layer;
first conductive patterns;
a second sensing insulating layer;
second conductive patterns;
a third sensing insulating layer; and
an organic pattern layer which overlaps the hole area, is disposed on the first sensing insulating layer and is covered on the second sensing insulating layer;
a cover organic layer disposed on the input sensor; and
a window disposed on the cover organic layer,
wherein a module hole which passes through the display panel, the input sensor, and the cover organic layer, which overlap the hole area, is defined,
each of the dam patterns surrounds the module hole, and
the second encapsulation inorganic layer, the first sensing insulating layer, the second sensing insulating layer, and the third sensing insulating layer contact each other on at least one top surface of the dam patterns.

2. The electronic device of claim 1, wherein the dam patterns comprise a first dam pattern to a fifth dam pattern spaced apart from each other in a direction toward the module hole on the pixel area, and
each of the first dam pattern to the fifth dam pattern comprises:
a first insulating pattern;
a first pattern disposed on the first insulating pattern;
a second pattern which contacts the first pattern; and
a second insulating pattern covering the second pattern, and
the second pattern protrudes between a side surface of the first insulating pattern and a side surface of the second insulating pattern and defines a tip part.

3. The electronic device of claim 2, wherein a boundary of the organic pattern layer is defined by the fourth dam pattern within the hole area, and
the second encapsulation inorganic layer, the first sensing insulating layer, the second sensing insulating layer, and the third sensing insulating layer contact each other on the fourth dam pattern.

4. The electronic device of claim 2, wherein the display panel comprises:
a first insulating layer disposed on the base layer;
a first semiconductor pattern disposed on the first insulating layer;
a second insulating layer covering the first semiconductor pattern and disposed on the first insulating layer;
a first gate overlapping the first semiconductor pattern and disposed on the second insulating layer;
a third insulating layer covering the first gate and disposed on the second insulating layer;
a second semiconductor pattern disposed on the third insulating layer;
a fourth insulating layer covering the second semiconductor pattern and disposed on the third insulating layer;
a second gate overlapping the second semiconductor pattern and disposed on the fourth insulating layer;
a fifth insulating layer covering the second gate and disposed on the fourth insulating layer;
a first connection electrode disposed on the fifth insulating layer and connected to the first semiconductor pattern through a first contact hole which passes through the second insulating layer to the fifth insulating layer pass;
a sixth insulating layer covering the first connection electrode and disposed on the fifth insulating layer;
a second connection electrode disposed on the sixth insulating layer and connected to the first connection electrode through a second contact hole which passes through the sixth insulating layer; and
a seventh insulating layer covering the second connection electrode and disposed on the sixth insulating layer,
wherein a light-emitting element of the light-emitting elements is connected to the second connection electrode through a third contact hole which passes through the seventh insulating layer passes.

5. The electronic device of claim 4, wherein the base layer comprises a first organic layer, a first inorganic layer disposed on the first organic layer, a second organic layer disposed on the first inorganic layer, and a second inorganic layer disposed on the second organic layer, which are sequentially laminated, and
each of the first organic layer and the second organic layer comprises polyimide, and each of the first inorganic layer and the second inorganic layer comprises an inorganic material.

6. The electronic device of claim 5, further comprising a light-blocking pattern overlapping the first semiconductor pattern and disposed within the second inorganic layer.

7. The electronic device of claim 4, wherein each of the first insulating layer to the fifth insulating layer comprises an inorganic material, and
each of the sixth and seventh insulating layers comprises an organic material.

8. The electronic device of claim 7, wherein the first insulating pattern comprises a same material as a material of the sixth insulating layer, and the second insulating pattern comprises a same material as a material of the seventh insulating layer, and
the first pattern comprises a same material as a material of the first connection electrode, and the second pattern comprises a same material as a material of the second connection electrode.

9. The electronic device of claim 4, wherein each of the first dam pattern to the fourth dam pattern further comprises a first dummy pattern overlapping the first pattern and disposed on the second insulating layer and a second dummy pattern overlapping the first dummy pattern and disposed on the third insulating layer.

10. The electronic device of claim 5, wherein the fifth dam pattern further comprises a dummy pattern disposed within the second inorganic layer, and
the first pattern of the fifth dam pattern is connected to the dummy pattern through a contact hole which passes through the second inorganic layer, the first insulating layer to the fifth insulating layer, and the first insulating pattern.

11. The electronic device of claim 2, wherein the organic pattern layer is disposed on an area between the first dam pattern and the second dam pattern, an area between the second dam pattern and the third dam pattern, and an area between the third dam pattern and the fourth dam pattern.

12. The electronic device of claim 11, wherein the second encapsulation inorganic layer, the first sensing insulating layer, the second sensing insulating layer, and the third sensing insulating layer contact each other on a top surface of the second dam pattern, a top surface of the third dam pattern, and a top surface of the fourth dam pattern.

13. The electronic device of claim 2, wherein the fourth dam pattern further comprises:
a first additional pattern disposed on the second insulating pattern; and
a second additional pattern disposed on the first additional pattern,
the fifth dam pattern further comprises a third additional pattern disposed on the second insulating pattern, and
each of the first additional pattern to the third additional pattern comprises an organic material.

14. The electronic device of claim 13, wherein a portion of the organic pattern layer is disposed between the fourth dam pattern and the fifth dam pattern, and
the second encapsulation inorganic layer, the first sensing insulating layer, the second sensing insulating layer, and the third sensing insulating layer contact each other on a top surface of the fourth dam pattern and a top surface of the fifth dam pattern.

15. The electronic device of claim 2, wherein the first encapsulation inorganic layer is covering the first dam pattern to the fifth dam pattern.

16. The electronic device of claim 2, wherein at least two tip parts of the tip parts respectively comprised in the first dam pattern to the fifth dam pattern face each other.

17. The electronic device of claim 1, wherein the first encapsulation inorganic layer and the second encapsulation inorganic layer contact each other on the at least one top surface of the dam patterns on which the second encapsulation inorganic layer, the first sensing insulating layer, the second sensing insulating layer, and the third sensing insulating layer contact each other.

18. The electronic device of claim 1, wherein each of the first sensing insulating layer, the second sensing insulating layer, and the third sensing insulating layer comprises an inorganic material.

19. The electronic device of claim 1, further comprising a fourth sensing insulating layer disposed between the cover organic layer and the third sensing insulating layer and comprising an organic material.

20. The electronic device of claim 1, further comprising a camera module overlapping the module hole.

21. An electronic device comprising:
a display panel displays an image based on input image data provided from the processor and comprising:
a base layer comprising:
an active area which comprises a hole area; and
a pixel area surrounding the hole area;
light-emitting elements disposed on the pixel area;
an encapsulation layer covering the light-emitting elements and comprising:
a first encapsulation inorganic layer;
an encapsulation organic layer; and
a second encapsulation inorganic layer; and
dam patterns disposed on the hole area;
a driving unit drives the display panel based on the input image data and a brightness value of the display panel;
an input sensor which are disposed on the encapsulation layer and comprising:
a first sensing insulating layer;
first conductive patterns;
a second sensing insulating layer;
second conductive patterns;
a third sensing insulating layer; and
an organic pattern layer which overlaps the hole area, is disposed on the first sensing insulating layer and is covered on the second sensing insulating layer;
a cover organic layer disposed on the input sensor; and
a window disposed on the cover organic layer,
wherein a module hole which passes through the display panel, the input sensor, and the cover organic layer, which overlap the hole area, is defined,
each of the dam patterns surrounds the module hole, and
the second encapsulation inorganic layer, the first sensing insulating layer, the second sensing insulating layer, and the third sensing insulating layer contact each other on at least one top surface of the dam patterns.

22. The electronic device of claim 21, wherein the dam patterns comprise a first dam pattern to a fifth dam pattern spaced apart from each other in a direction toward the module hole on the pixel area, and
each of the first dam pattern to the fifth dam pattern comprises:
a first insulating pattern;
a first pattern disposed on the first insulating pattern;
a second pattern which contacts the first pattern; and
a second insulating pattern covering the second pattern, and
the second pattern protrudes between a side surface of the first insulating pattern and a side surface of the second insulating pattern and defines a tip part.
